(19) United States
(12) Patent Application Publication
(10) Pub. No.: US 2011/0012319 A1
(43) Pub. Date: Jan. 20, 2011

(54) Recreational Board

(76) Inventors: Chris Kuczynski, San Diego, CA (US); Gabriel Penix, San Diego, CA (US)

Correspondence Address: Chris Kuczynski, Esq., 6755 Mira Mesa Blvd., Suite 123-435, San Diego, CA, 92121, US

(21) Appl. No.: 12/502,999

(22) Filed: Jul. 14, 2009

(51) Int. Cl. A63C 1/02; H01M 10/46; F21L 4/00; H01L 31/00

(52) U.S. Cl. 280/11.115; 320/101; 362/183; 136/243

(57) ABSTRACT

The embodiments described are directed to a solar board having an elongated base for supporting the weight of one or more riders. The elongated based includes an upper surface, a lower surface, a tail, and a nose. A solar cell component disposed between the nose and the tail and proves electricity to a heating component.

### TECHNICAL FIELD

The embodiments described herein are generally directed to a recreational board for activities, the board being used for snowboarding, skiing, skydiving, or any activity where a human being stands on the board for recreational activity.

### BACKGROUND

When snowboarding during time of snow or under conditions when snow is loose, snow accumulates on a snowboard weighing the snowboard down. An object of this disclosure is to minimize snow accumulation on a recreational board such as a snowboard during snowboarding. Another object of this disclosure is to provide electrical power by solar cells or other electrical power components to devices that are both integrated and external to the recreational board.

### SUMMARY

The embodiments and methods described herein are generally directed to a solar board having an elongated base for supporting the weight of one or more riders. The elongated based includes an upper surface, a lower surface, a tail, and a nose. A solar cell component disposed between the nose and the tail and proves electricity to a heating component.

### BRIEF DESCRIPTION OF THE DRAWINGS

The features and inventive aspects of the present disclosure will become more apparent upon reading the following detailed description, claims, and drawings, of which the following is a brief description:

FIG. 1A is an elevated perspective view of a solar board according to one contemplated embodiment;

FIG. 1B is an elevated perspective view of the solar board of FIG. 1A showing an example of several solar cells and a one exemplary heating component layout;

FIG. 2 is an elevated perspective view of a solar board showing a pair of elevated bindings;

FIG. 3A is a top plan view of a solar board illustrating a heating component with one electrical storage device;

FIG. 3B is a top plan view of a solar board illustrating three heating components with two electrical storage devices;

FIG. 4A is a top plan view of a solar board illustrating an exemplary layout of a plurality of solar cells and one electrical storage device;

FIG. 4B is a top plan view of a solar board illustrating an exemplary layout of a plurality of solar cells in two sections and two electrical storage devices;

FIG. 5A is a sectional view of an exemplary connection component between two solar cells connected at an upper portion of the solar cells; and

FIG. 5B is a sectional view of an exemplary connection component between two solar cells connected at an inner wall of the solar cells and having an upper layer.

### DETAILED DESCRIPTION

Referring now to the drawings, illustrative embodiments are shown in detail. Although the drawings represent the embodiments, the drawings are not necessarily to scale and certain features may be exaggerated to better illustrate and explain an innovative aspect of the disclosure. Further, the embodiments described herein are not intended to be exhaustive or otherwise limit or restrict the claimed invention to the precise form and configuration shown in the drawings and disclosed in the following detailed description.

The term “board” as used throughout the specification is defined hereinafter to be sufficient for supporting the weight of one or more riders on snow or a hard surface terrain including at least one ski, a snowboard, or an all-terrain board. The term board includes use for personal, recreational, and professional use.

The term “solar power” as used throughout the specification is defined hereinafter to include and is not limited to: at least one solar cell or photovoltaic cell that converts sunlight or any unspecified light source into electricity. The term solar cell includes the term photovoltaic cell.

The term “solar cell component” as used throughout the specification is defined hereinafter to include and is not limited to: at least one solar cell; assemblies of solar cells that are used to make at least one solar panel, solar module, or photovoltaic array.

The term “photovoltaic” as used throughout the specification is defined hereinafter to include and is not limited to: is the field of technology and research related to the application of solar cells in producing electricity for practical use.

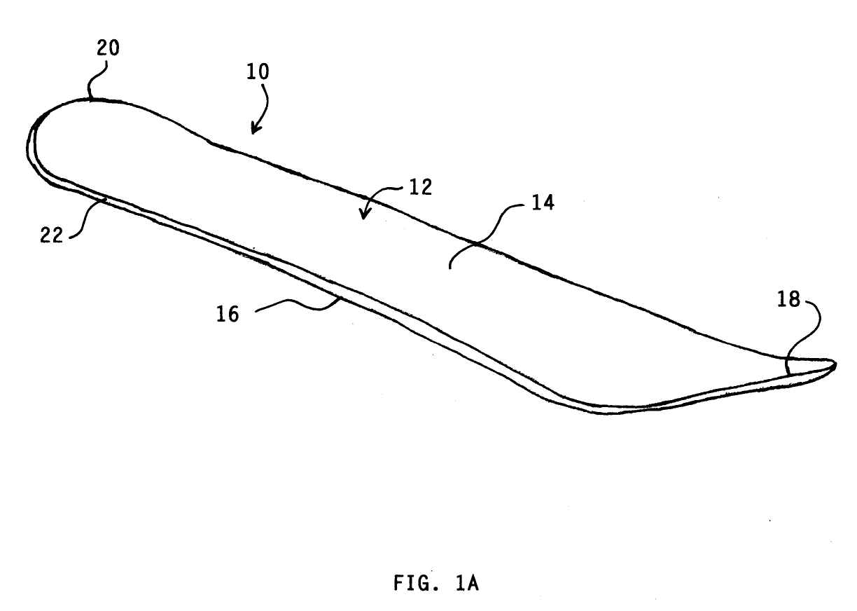

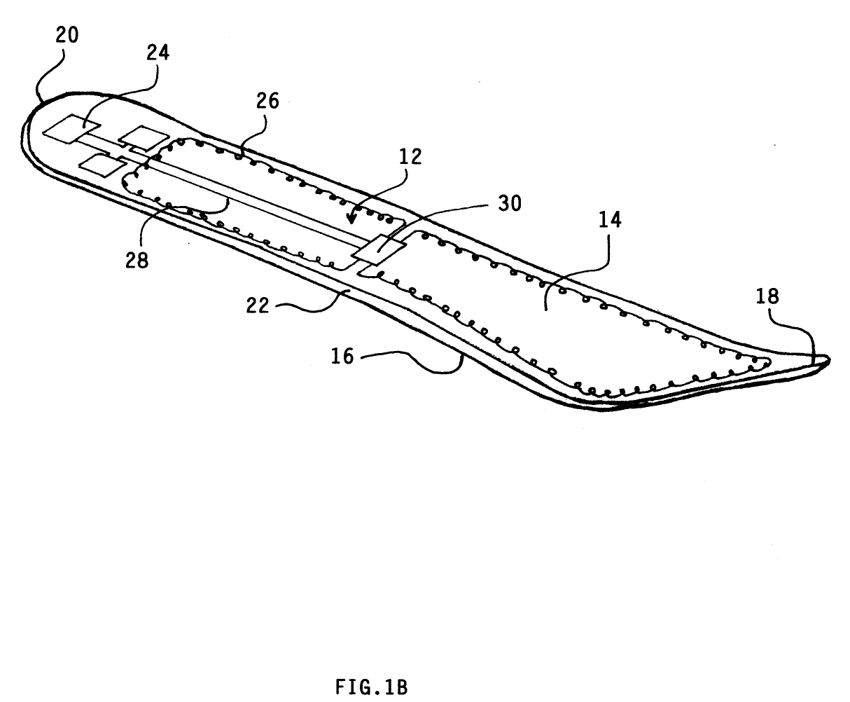

An exemplary object of the disclosure, according to the teaching disclosed herein, is to provide a recreational board 10 for recreational activities as shown in FIG. 1A having at least one elongated member 12. The elongated member 12 includes an upper surface 14, a lower surface 16, a nose 18 at one end of the elongated member 12 and a tail 20 at an opposite end of the elongated member 12. An edge 22 is disposed at least partially between the upper surface 14 and the lower surface 16 for at least a portion of the elongated member 12. The recreational board 10 may be manufactured from any of a variety or combination of suitable materials, such as metals, wood, epoxy, fiberglass, ceramic, graphite, polymers, composites or any synthetic materials.

FIG. 1B illustrates an elongated member 12 having at least one solar cell 24 for providing electrical power to a board component. One exemplary board component illustrated in FIG. 1B is a heating component 26 that raises the temperature level of the elongated member 12 further discussed below. The solar cells 24 may be any type of solar cells including thin film solar cells disposed above the loser surface 16. FIG. 1B illustrates the solar cells 24 disposed below a transparent layer (not shown). The solar cells 24 are placed in electrical communication by elements 28 with an electrical storage component 30 such as a battery and/or a capacitor. The electrical storage component 30 may be disposed anywhere above the lower surface 16 in electrical communication with one or more board components. The recreational board 10 may also include adapters for recharging the electrical storage component 30 by way of an electrical outlet or any power source. The adapters may be of any type, size, voltage, or amperage. Further, the elongated member 12 may also include a second adapter for providing electrical power to at least one external device such as a portable music player, cellular telephone, any handheld electronic device, and the like. These adapters may be located anywhere above the lower surface 16 and either be disposed on the elongated member 12 or be externally located from the elongated member 12. By way of example, these adapters may be disposed on or in the bindings, boots, or placed on the user.

In one embodiment of the disclosure, the solar cells 24 are disposed above a reflective layer for increasing solar collection by the solar cells 24 allowing the solar cells 24 to collect energy from both the upper portion and the lower portion of the solar cells 24.

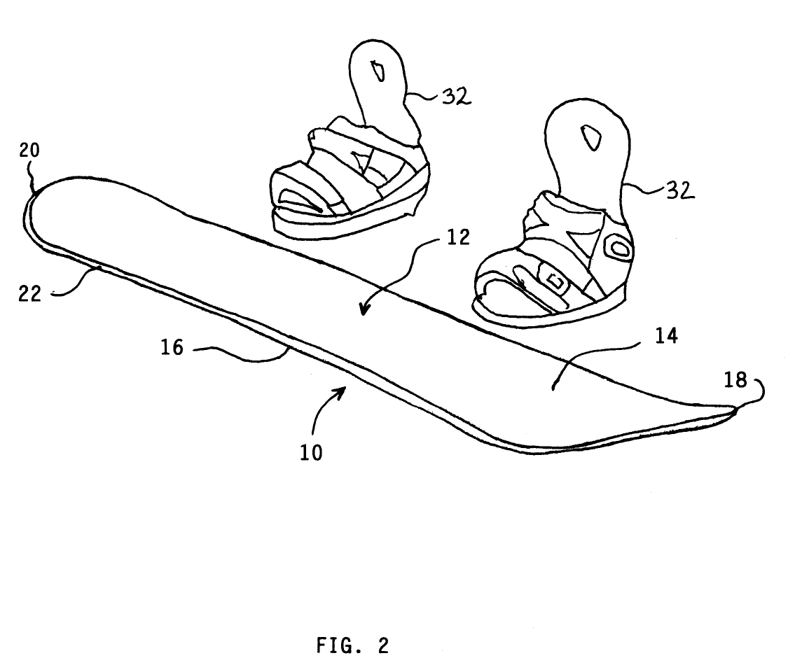

FIG. 2 illustrates another embodiment provided in accordance with the teachings of the present disclosure showing an elongated member 12 with binding 32 for snowboarding. The binding 32 are fixed to the elongated member 12 at a user desired location on the upper surface 14. The bindings 32 may be in electrical communication with the electrical storage component 30 and/or the solar cell 24 for providing electricity to light components disposed within the bindings 32, boots (not shown), or on the user (not shown). The bindings 32 may also provide electrical power from the electrical storage component 30 and/or the solar cell 24 to the boots for any electrical components including heating components disposed within the boots. The bindings 32 may also provide electrical power to boots for lights disposed within the boots or on the user.

The electrical power may be disposed on any one or more of the following: the elongated member 12, the boot binding 32, the boots, or and external component.

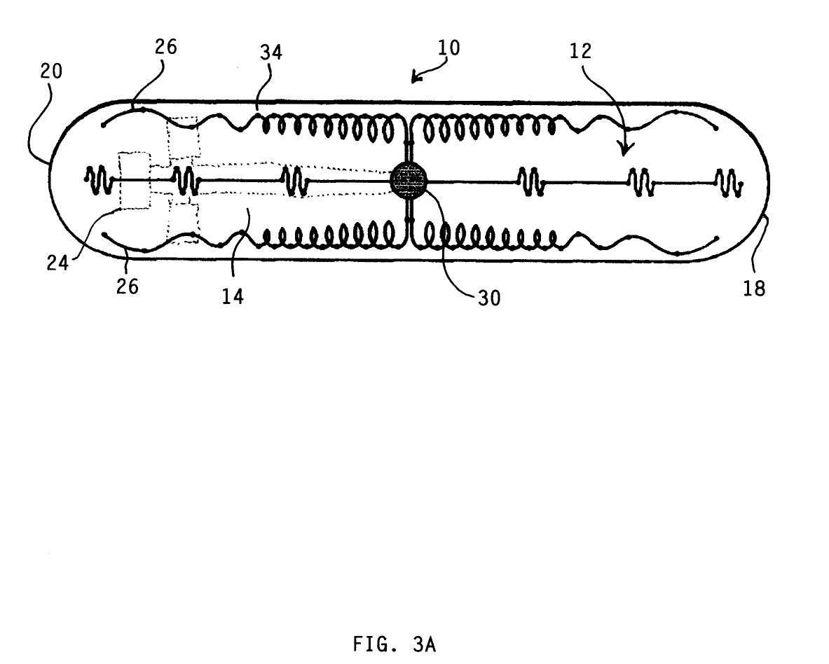

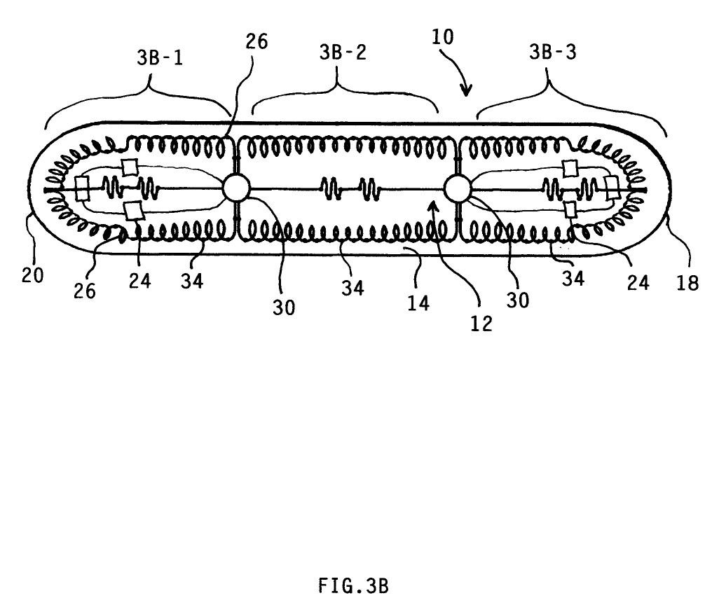

Turning to FIG. 3A and FIG. 3B, two exemplary illustrations of a recreational board 10 having light components 34, provided in electrical communication with at least one heating component 26. Light components 34 and their possible location on the elongated member 12 are discussed in U.S. Pat. No. 7,232,243, herein incorporated by reference in its entirety and U.S. Pat. No. 6,802,636 herein incorporated by reference in its entirety. In addition, the light components 34 may derive power from a board component such as the heating component 26 and/or directly from one or more solar cells 24.

FIG. 3A illustrates the heating component 26 in electrical communication with one electrical storage component 30 and FIG. 3B illustrates the heating component 26 in electrical communication with two electrical storage components 30 and divided in three sections, a first section 3B-1, a second section 3B-2, and a third section 3B-3 of the elongated member 12. FIG. 3B is exemplar of one of many possible combinations of a primary and/or at least one other power source having at least one electrical storage component 30 providing power to a board component such as the heating component 26. Each electrical storage component 30 may provide power to an individual section of the elongated member 12 or any combination of sections. Further, the primary and/or at least on other power source to the one or more sections may be provided by the solar cells 24 grouped as one solar cell group or sections of solar cells 24.

The heating component 26 may be at least partially or completely disposed above or below the upper surface 14 and in electrical communication with one or more power sources such as one or more electrical storage components 30 and/or one or more solar cells 24. The heating component 26 provides the user of the recreational board 10 with a selective option of heating the elongated member 10 a selected or predetermined amount of heat thereby creating a surface that minimizes the accumulation of snow or ice on the elongated member 12.

In one embodiment of the disclosure, the heating component 26 includes any one or more of the following technologies: Nickel-Chromium Alloy wire, ribbon, strip, tubular element, Positive Thermal Coefficient (PTC), ceramic including but not limited to barium titanate and lead titanate composites, thin films, wire element heaters, and thick film technology. Other possible technologies include but are not limited to including platinum, molybdenum disilicide, molybdenum and silicon carbide.

The heating component 26 includes any of the above provided materials including thin film technology that may be placed on any layer of the recreational board 10 including above or below the solar cells 24 or integrated on the same layer as the solar cells.

Selection components include one or more selection switches and/or selection dials that may be disposed anywhere on the elongated member 12 in electrical communication with any of the board components such as the heating component 26 and any of the power sources such as the electrical storage component 30 and/or the solar cell 24. At least one additional selection component may be disposed on either/or the binding or the boot. Further, automated switches may be placed anywhere on the elongated member 12 for safety purposes with predetermined functions. For instance, one example of an automated switch may be a switch that disconnects or limits the flow of electricity from the solar cells 24 to the electrical storage component to prevent or limit an overcharged state. Another example of an automated switch may be one that prevents the heating component 26 from overheating by automatically terminating or reducing the amount of electrical power allowed to reach the heating component 26.

The heating component 26 is illustrated as being in a coiled state. However, the path of the heating component 26 may take any path and be any shape. and may include any material of composition. In one exemplary embodiment, the heating component 26 is disposed in a heating component layer that is located under a layer of solar cells 24. In another exemplary embodiment, the heating component 26 is disposed on the same layer as the solar cells 24 placed between the soar cells 24.

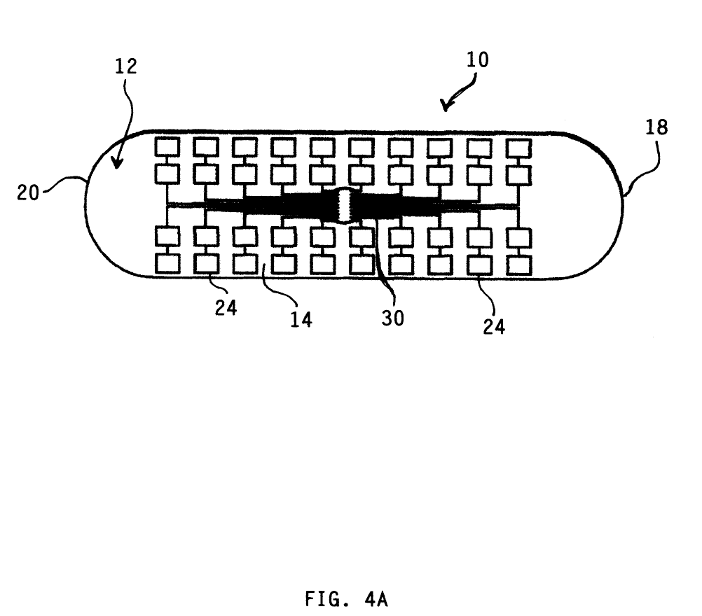

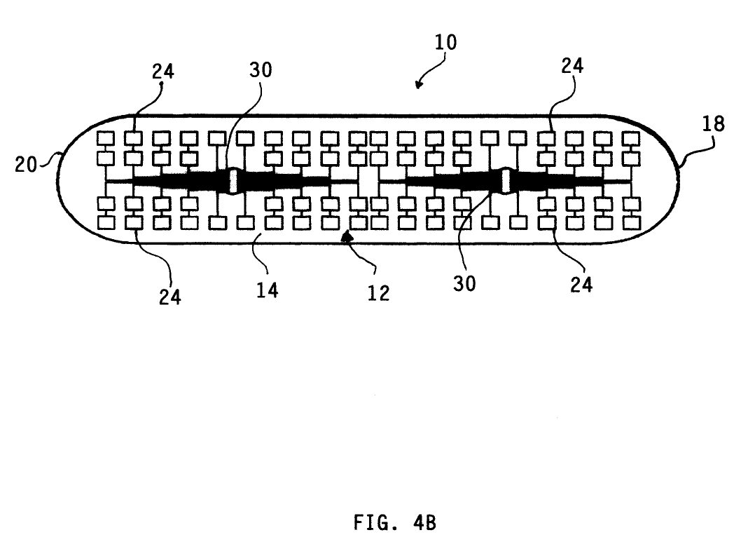

Turning now to FIG. 4A and FIG. 4B, two exemplary illustrations of a recreational board 10 having solar cells 24 in electrical communication with at least one electrical storage component 30. The pattern or location of the solar cells 24 varies by the electrical demands and location of the user bindings. The solar cells 24 may be placed in either a grouping of parallel or serial solar cells 24 for the desired voltage and amperage. The solar cells 24 may be in electrical communication with the electrical storage component 30 only, or act as a primary electrical power source to the board components with excess power being diverted to the electrical components 30. The solar cells 24 may also be configured in the primary and/or at least one additional power source orientation as shown in FIG. 4B allowing sectioning of the board as discussed above. The solar cells 24 may also provide power to through the bindings to a heating component in the user's boots or an additional electrical storage device located proximate the user's boots.

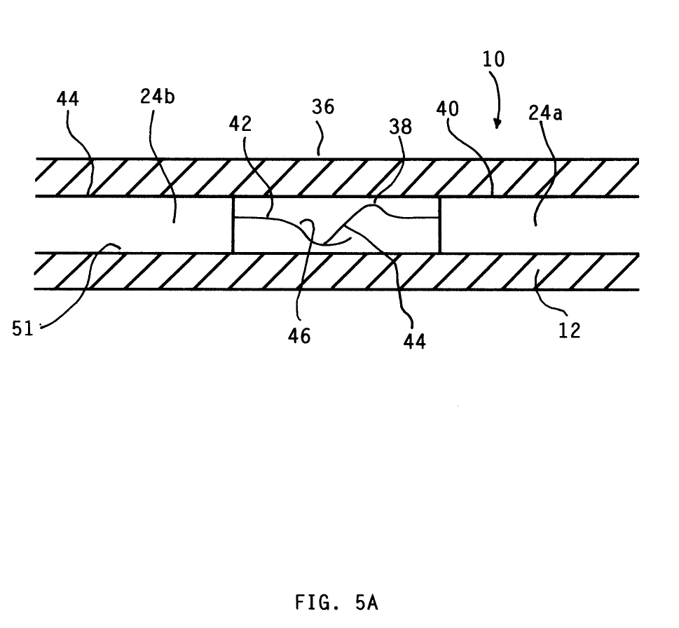

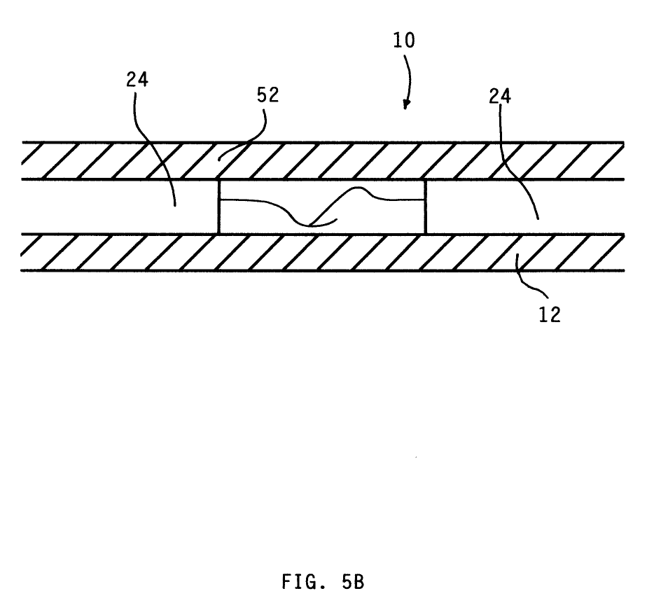

FIGS. 5A and 5B illustrate three exemplary embodiments of a connector or connection component between two solar cells 24 contemplated by this disclosure. There are many other connections possible but these three connection methods are disclosed as three possible solutions to maintaining a connection between two solar cells 24 on a recreational board 10 that is under various pressures and strains. As the recreational board 10 bends and moves under the weight of a recreational rider, the connections between the solar cells 24 may be damaged.

In FIG. 5A, two solar cells 24 are shown disposed on an first surface 51 of the elongated member 12 with a connection component 36 disposed between two solar cell 24a and 24b. The connection component 36 includes a first connector 38 disposed on an first upper surface 40 of a first solar cell 24a in a parabolic curve pointing in a downward direction. The connection component 36 also includes a second connector 42 disposed on a second upper surface 44 of a second solar cell 24b extending downwardly in an upward curved manner. The lower surface 44 of the first connector 38 is in electrical communication with the upper surface 46 of the second connector 42. As the two solar cells 24a and 24b move and bend in relation to each other, the connection component 36 maintains electrical communication with the two solar cells, 24a and 24b. A layer 52 is disposed above solar cells 24. One embodiment of the disclosure includes solar cells 24 disposed on the elongated member 12 having the connection component 36 within a solar cell layer with no additional layer above the solar cell 24. FIG. 5B is similar to FIG. 5A except that the first connector is disposed on a first wall 48 of the first solar cell 24a and the second connector 42 is disposed on a second wall 50 of the second solar cell 24b. FIG. 5B may include the layer 52 disposed above the solar cells 24.

Now referring to FIGS. 1A-5B of this disclosure that includes a method of generating electricity by providing the elongated member 12 for supporting the weight of one or more riders having the upper surface 14, the lower surface 16, the tail 20, and the nose 18. The method further includes placing a solar cell component 24 between the nose 18 and the tail 20. The method includes generating electricity from the solar cell component 24 for the heating component 26, the heating component 26 is disposed between the nose 18 and the tail 20. The method further includes placing the electrical regulation component in electrical communication with the solar cell 24. The method even further includes placing the solar cell 24 in electrical communication with a component disposed at least partially above the upper surface 14. The method also includes providing a light component 34 in electrical communication with the solar cell component 24.The method includes providing electricity to the electrical storage component 30 in electrical communication with at least one solar cell 24.

The preceding description has been presented only to illustrate and describe exemplary embodiments of the methods and systems of the present disclosure. It is not intended to be exhaustive or to limit the invention to any precise form disclosed. It will be understood by those skilled in the art that various changes may be made and equivalents may be substituted for elements thereof without departing from the scope of the claimed invention. In addition, many modifications may be made to adapt a particular situation or material to the teachings of the disclosure without departing from the essential scope. Therefore, it is intended that the claimed invention not be limited to the particular embodiment disclosed as the best mode contemplated for carrying out the claimed invention, but that the claimed invention will include all embodiments falling within the scope of the claims. The disclosure may be practiced otherwise than is specifically explained and illustrated without departing from its spirit or scope. The scope of the claimed invention is limited solely by the following claims.

What is claimed is:

1. A recreational board comprising: an elongated base for supporting the weight of one or more riders having an upper surface, a lower surface, a tail, and a nose, wherein a electrical power component is disposed between said nose and said tail and said electrical power component provides electrical power to a heating component.

2. The recreational board of claim 1, wherein said electrical power component is a solar cell component disposed between said nose and said tail.

3. The recreational board of claim 1, wherein said electrical power component is a battery component disposed between said nose and said tail.

4. The recreational board of claim 1, wherein at least one light component is in electrical communication with said electrical power component.

5. The recreational board of claim 1, wherein at least one light component is in electrical communication with said heating component.

6. The recreational board of claim 2, wherein said solar cell component provides electrical power to a battery component disposed between said nose and said tail.

7. The recreational board of claim 2, wherein said recreational board includes a reflective layer between said solar cell component and said lower layer.

8. The recreational board of claim 1, wherein said recreational board is configured to be in electrical communication with a boot binding.

9. The recreational board of claim 8, wherein said boot binding includes a light component in electrical communication with said electrical power component.

10. The recreational board of claim 1, wherein said recreational board is configured to be in electrical communication with a boot.

11. The recreational board of claim 10, wherein said boot includes a light component in electrical communication with said electrical power component.

12. The recreational board of claim 1, wherein said recreational board includes an electrical regulation component in electrical communication with said electrical power component.

13. The recreational board of claim 2, wherein said recreational board includes an electrical regulation component in electrical communication with said solar cell component.

14. The recreational board of claim 2, wherein said recreational board includes an electrical storage component in electrical communication with said solar cell component.

15. The recreational board of claim 3, wherein said recreational board includes a first adapter that accepts external electrical power for recharging said battery component.

16. The recreational board of claim 2, wherein said recreational board includes a second adapter for providing power to external devices.

17. A recreational board comprising: an elongate base for supporting the weight of one or more riders having an upper surface, a lower surface, a tail, and a nose, a solar cell component disposed between said nose and said tail, said solar cell component proving electricity to a heating component wherein said recreational board includes an electrical regulation component in electrical communication with said solar cell component.

18. The recreational board of claim 17, wherein said solar board includes a light component in electrical communication with said solar cell component.

19. The recreational board of claim 17, wherein said solar cell component provides electricity to a battery component.

20. A method of generating electricity comprising: (a) providing an elongated member for supporting the weight of one or more riders having an upper surface, a lower surface, a tail, and a nose; (b) placing a solar cell component between said nose and said tail; and (c) generating electricity from said solar cell component, said elongated member configured to provided electrical power for both a component in mechanical communication with said elongated member and an external component.

21. The method of claim 20, including providing electrical power for a heating component, said heating component being disposed between said nose and said tail;

22. The method of claim 20, further placing an electrical regulation component in electrical communication with said solar cell component.

23. The method of claim 20, further placing said solar cell component in electrical communication with an attachable component, said attachable component being disposed at least partially above said upper surface.

24. The method of claim 20, further providing a light component in electrical communication with said solar cell component.

25. The method of claim 20, further providing electricity to a electrical storage component in electrical communication with said solar cell component.
